(19) United States
(12) Patent Application Publication
(10) Pub. No.: US 2021/0305017 A1
(43) Pub. Date: Sep. 30, 2021

(54) INDUCTIVELY COUPLED PLASMA CHAMBER HEATER FOR CONTROLLING DIELECTRIC WINDOW TEMPERATURE

(71) Applicant: Lam Research Corporation, Fremont, CA (US)

(72) Inventors: Gordon Peng, San Jose, CA (US); Craig Rosslee, San Jose, CA (US); Shen Peng, Dublin, CA (US); James Chris Vetter, Pine Grove, CA (US)

(21) Appl. No.: 17/214,741

(22) Filed: Mar. 26, 2021

Related U.S. Application Data
(63) Continuation of application No. 63/003,215, filed on Mar. 31, 2020.

(51) Int. Cl. H01J 37/32

(52) U.S. Cl. CPC H01J 37/32119; H01J 2237/24585

(57) ABSTRACT

A system for heating a dielectric window of a plasma processing chamber is provided. In one example, the method includes the use of a heating element. The heating element includes a dielectric disc and a conductive line formed in the dielectric disc. The conductive line includes a plurality of loops oriented radially around the dielectric disc. Each loop extends from a radial periphery of the dielectric disc toward a center of the dielectric disc. Each loop of the conductive line has an inward segment coupled to a return segment by a switchback segment. The inward segment is vertically aligned with the return segment.

### CLAIM OF PRIORITY

This application claims priority under 35 U.S.C. 119(e) to U.S. Provisional Patent Application No. 63/003,215, filed Mar. 31, 2020, the disclosure of which is incorporated herein by reference in its entirety for all purposes.

### 1. FIELD OF THE INVENTION

The present embodiments relate to semiconductor fabrication, and more particularly, to ways of controlling the heat of a dielectric window used in plasma chambers for processing wafers.

### BACKGROUND

### 2. Description of the Related Art

In semiconductor manufacturing, etching processes are commonly and repeatedly carried out. As is well known to those skilled in the art, there are two types of etching processes: wet etching and dry etching. One type of dry etching is plasma etching performed using an inductively coupled plasma chamber.

Plasma contains various types of radicals, as well as positive and negative ions. The chemical reactions of the various radicals, positive ions, and negative ions are used to etch features, surfaces and materials of a wafer. The effectiveness of an etching process may be based on the performance of the plasma, which in turn, affects the quality of the processed wafers.

In inductively coupled plasma chambers, a dielectric window is generally disposed above a substrate support, and an inductive coil is disposed over the dielectric window. Because the inductive coil delivers high levels of power, the inductive coil will cause an elevation in temperature that is transferred to the dielectric window. Although elevated temperatures in the dielectric window are expected in steady state operation, these temperatures can vary significantly at startup and in between process steps. Unfortunately, uncontrolled variations in temperature of the dielectric window may result in reducing one or more etch performance metrics.

In view of these technical concerns, there is a need to control the temperature variations in the dielectric window of an inductively coupled plasma chamber.

It is in this context that embodiments of the inventions arise.

### SUMMARY

Implementations of the present disclosure include devices, methods, and systems for heating a dielectric window of a plasma processing chamber. In some embodiments, a heating element is disposed over the dielectric window and below the coils of the plasma processing chamber. The heating element is configured to produce heat when its power supply is activated, which in turn provides controlled heat to the dielectric window. In some embodiments, the heating element may be used to place the temperature of the dielectric window at a steady state temperature so that wafers are fabricated at a consistent temperature. In another embodiment, the orientation and dimensions of the heating element may be configured to prevent and/or minimize radio frequency (RF) coupling that may arise.

In one embodiment, a heating element is disclosed. The heating element includes a dielectric disc and a conductive line formed in the dielectric disc. The conductive line includes a plurality of loops oriented radially around the dielectric disc. Each loop extends from a radial periphery of the dielectric disc toward a center of the dielectric disc. Each loop of the conductive line has an inward segment coupled to a return segment by a switchback segment. The inward segment is vertically aligned with the return segment.

In another embodiment, a system for heating a dielectric window of a plasma processing chamber is disclosed. The system includes a process chamber. The process chamber includes a dielectric window in which the dielectric window is oriented over a substrate support. The system further includes a coil that is defined by an inner coil and an outer coil. The coils are oriented over the dielectric window, and coils are defined by plurality of circular coils. The system further includes a heating element disposed over the dielectric window and below the coils. The heating element includes a dielectric disc and a conductive line formed in the dielectric disc. The conductive line includes a plurality of loops oriented radially around the dielectric disc. Each loop extends from a radial periphery of the dielectric disc toward a center of the dielectric disc. Each loop of the conductive line has an inward segment coupled to a return segment by a switchback segment. The inward segment is vertically aligned with the return segment.

Other aspects and advantages of the disclosure will become apparent from the following detailed description, taken in conjunction with the accompanying drawings, illustrating by way of example the principles of the disclosure.

### BRIEF DESCRIPTION OF THE DRAWINGS

The disclosure may be better understood by reference to the following description taken in conjunction with the accompanying drawings in which:

FIG. 1 illustrates an embodiment of a plasma processing system utilized for etching operations, in accordance with an implementation of the disclosure.

FIG. 2A illustrates an embodiment of a conductive line before it is encased in a dielectric disc, in accordance with an implementation of the disclosure.

FIG. 2B illustrates an enlarged partial view of a section of the conductive line shown in FIG. 2A, in accordance with an implementation of the disclosure.

FIG. 2B-1 illustrates an embodiment of a heating element, in accordance with an implementation of the disclosure, in accordance with an implementation of the disclosure.

FIG. 2B-2 illustrates an enlarged partial view of a section of the heating element shown in FIG. 2B-1, in accordance with an implementation of the disclosure.

FIG. 2C illustrates an embodiment of a heating element and a section view of the heating element, in accordance with an implementation of the disclosure.

FIG. 3A illustrates a partial top view of a plasma processing system, in accordance with an implementation of the disclosure.

FIG. 3B illustrates a partial cross-sectional view of the outer coil, the heating element, and the dielectric window taken along line A-A of FIG. 3A, in accordance with an implementation of the disclosure.

FIGS. 4A and 4B illustrate various embodiments of the heating element and the respective positions of the outer coil, inner coil, and dielectric window taken along line B-B of FIG. 3A, in accordance with an implementation of the disclosure.

FIGS. 5A-5E illustrate an embodiment of a temperature plot of the dielectric window and the respective power activity of the RF power and the heater power over a period of time, in accordance with an implementation of the disclosure.

FIG. 6 illustrates an embodiment of a block diagram of a heater used to connect to the heating element so that the heating element can produce heat when the heater is activated, in accordance with an implementation of the disclosure.

### DETAILED DESCRIPTION

The following implementations of the present disclosure provide devices, methods, and systems for controllability heating a dielectric window of an inductively coupled plasma (ICP) chamber for processing wafers. One example of an ICP chamber is a transformer coupled plasma (TCP) chamber where the coils are disposed horizontally over a dielectric window. By way of example, a heating element may be used to controllably heat the dielectric window of the plasma processing chamber at startup, between operations, or when needed to maintain a target steady state temperature of the dielectric window. By controlling the temperature of the dielectric window, it is possible to reduce the variations experienced by the plasma during processing, which in turn assists in improving etch performance.

Some existing ways of heating the dielectric window of an ICP chamber include the use of planar heaters and air-blowers. These methods can result in several disadvantages. For example, the use of some existing planar heaters may result in significant RF coupling, which can negatively affect etch rates. Similarly, air-blowers can be inefficient in controlling temperature variations, may increase noise and can result in increased power consumption.

In view of these issues, one disclosed embodiment includes a system for heating a dielectric window of a plasma processing chamber. In some embodiments, the chamber includes a dielectric window oriented over a substrate support. The system includes transformer coupled plasma (TCP) coils that are disposed over the dielectric window and are configured for receiving radio frequency (RF) power. In this embodiment, a heating element may be disposed between the TCP coils and the dielectric window. In one embodiment, a power source is connected to the heating element to produce heat, which in turn provides heat to the dielectric window. In some embodiments, the heating element may be activated during a warm-up period to deliver heat to the dielectric window so that the temperature of the dielectric window can reach a desired steady state temperature (e.g., approximate processing temperature). By way of example, by maintaining the dielectric window at a steady state temperature during processing steps, it is possible to remove variations in plasma conditions that could reduce etch performance. In one embodiment, the configuration and orientation of the heating element is designed to minimize RF coupling that may occur between the TCP coils and the heating element. RF coupling has the negative impact of reducing the amount of power delivered to the plasma during processing.

In accordance with one embodiment, the heating element is defined by a conductive line formed in a dielectric disc. The conductive line has a plurality of loops oriented radially around the dielectric disc where each loop extends from a radial periphery of the dielectric disc toward a center of the dielectric disc. Each loop of the conductive line has an inward segment coupled to a return segment by a switchback segment. The switchback segment of each loop forms a shape of a semi-circle and is configured to couple the inward segment to the return segment. The inward segment is vertically aligned, e.g., in the z-direction, with the return segment along a thickness of the dielectric disc. As noted above, the configuration of the conductive line is designed to minimize RF coupling, which in turn will minimize the loss of RF power delivered by the TCP coils to the plasma.

With the above overview in mind, the following provides several example figures to facilitate understanding of the example embodiments.

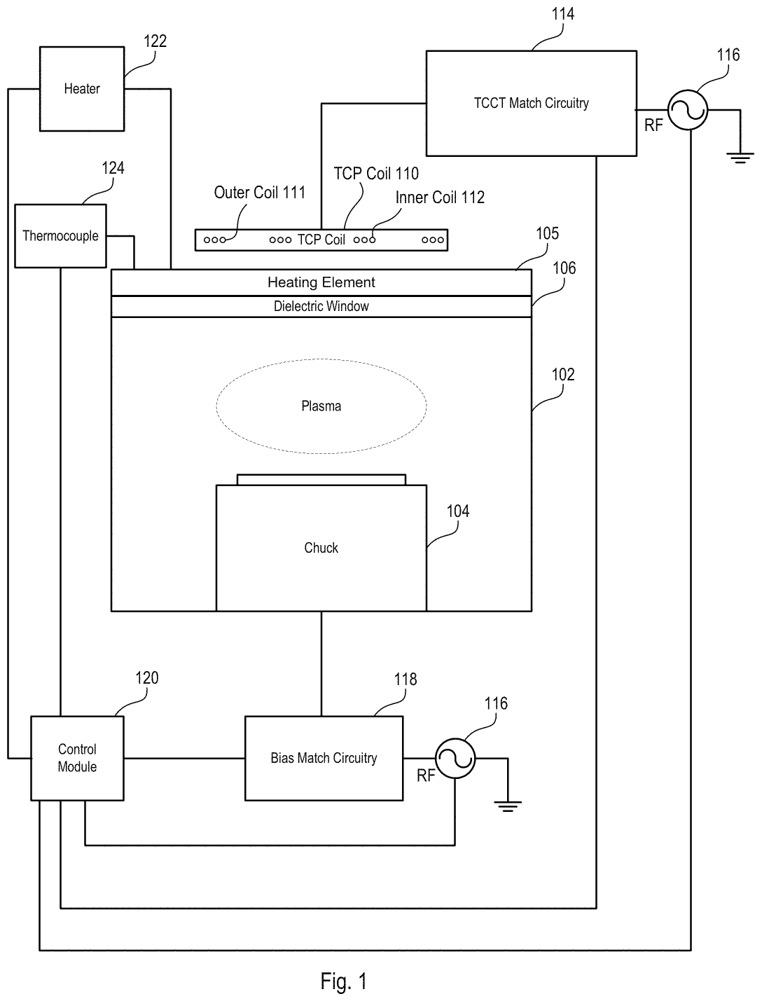

FIG. 1 illustrates an embodiment of a plasma processing system utilized for etching operations. The system includes a chamber 102 that includes a chuck 104, a dielectric window 106, and TCP coils 110 (inner and outer). The chuck 104 can be an electrostatic chuck for supporting the substrate when present. The system further includes a heating element 105, a heater 122, a thermocouple 124, a TCCT Match Circuitry 114, a bias match circuitry 118, RF generator 116, and a control module 120.

As shown in FIG. 1, the heating element 105 is disposed between the TCP coil 110 and the dielectric window 106. In some embodiments, the heating element 105 is configured for placement over the dielectric window 106 and is in close proximity to the TCP coils 110. In some embodiments, the heating element 105 may directly lay on top of the dielectric window 106. In another embodiment, the heating element 105 may be secured to the dielectric window using clamps, screws, brackets, or any other device that will prevent the heating element from shifting away from its initial position. The heating element 105 is configured to deliver heat to the dielectric window 106 so that the dielectric window can reach a steady state temperature or can maintain a desired temperature during processing. In some embodiments, the steady state temperature can be an approximate process temperature of the dielectric window 106 when RF power is supplied to the TCP coils 110 using RF generator 116.

In some embodiments, the heater 122 is connected to the heating element 105 and is configured to deliver power to the heating element 105 so that the heating element 105 produces heat when the heater 122 is activated. In some embodiments, when the heater 122 is activated, the heating element 105 heats the dielectric window 106 so that the dielectric window can reach a steady state temperature. By way of example, at the start of a processing operation, the heating element 105 can be activated to place the dielectric window at a steady state temperature. Once the RF generator 116 is activated to provide RF power to the TCP coils, the heating element 105 can be turned off. This is possible, as the power provided via the TCP coils 110 will maintain the dielectric window 106 in the steady state temperature. Accordingly, the heating element 105 is designed to provide heat to the dielectric window 106 at start of a processing operation, so that active processing begins with the dielectric window 106 already at the desired steady state temperature. Once the TCP coils 110 are providing the RF power, the TCP coils 110 will continue to maintain the dielectric window 106 at said steady state. As will be described below, the heating element 105 can also be activated in between processing steps, so that the dielectric window 106 remains in said steady state, and thus reduces variations that could impact etch performance.

In another embodiment, the thermocouple 124 may be connected to the heating element 105 to determine the temperature of the heating element 105 and to approximate the temperature of the dielectric window 106. For example, if the thermocouple 124 senses a temperature that suggests the dielectric window 106 is outside a steady state temperature, the heater 122 can be activated so that the heating element 105 can provide heat to the dielectric window 106 so it can reach a steady state temperature.

Further shown is a bias RF generator 116, which can be defined by one or more generators. If multiple generators are provided, different frequencies can be used to achieve various tuning characteristics. A bias match circuitry 118 is coupled between the RF generators 116 and a conductive plate of the assembly that defines the chuck 104. The chuck 104 also includes electrostatic electrodes to enable the chucking and dechucking of the wafer. Broadly, a filter and a direct current (DC) clamp power supply can be provided. Other control systems for lifting the wafer off of the chuck 104 can also be provided. Although not shown, pumps are connected to the chamber 102 to enable vacuum control and removal of gaseous byproducts from the chamber 102 during operational plasma processing.

In some embodiments, the dielectric window 106 can be defined from a ceramic type material. For example, the dielectric window 106 can be made from Quartz. Other dielectric materials are also possible, so long as they are capable of withstanding the conditions of a semiconductor etching chamber. The temperature will depend on the etching process operation and specific recipe. The chamber 102 will also operate at vacuum conditions. Although not shown, chamber 102 is typically coupled to facilities when installed in a clean room, or a fabrication facility. Facilities include plumbing that provide processing gases, vacuum, temperature control, and environmental particle control.

In some embodiments, these facilities are coupled to chamber 102, when installed in the target fabrication facility. Additionally, chamber 102 may be coupled to a transfer chamber that will enable robotics to transfer semiconductor wafers into and out of chamber 102 using typical automation.

In some embodiments, the TCCT match circuitry 114 enables dynamic tuning of power provided to the inner coils 112 and outer coils 111. The TCP coils are coupled to the TCCT match circuitry 114 which includes connections to the inner coil (IC) 112, and outer coil (OC) 111. In one embodiment, the TCCT match circuitry 114 is configured to tune the TCP coils to provide more power to the inner coil 112 versus the outer coil 111. In another embodiment, the TCCT match circuitry 114 is configured to tune the TCP coils to provide less power to the inner coil 112 versus the outer coil 111. In another embodiment, the power provided to the inner coil and the outer coil will be to provide an even distribution of power and/or control the ion density in a radial distribution over the substrate (i.e., wafer, when present). In yet another embodiment, the tuning of power between the outer coil and the inner coil will be adjusted based on the processing parameters defined for that etching being performed on the semiconductor wafer disposed over chuck 104.

In some embodiments, the system may include a control module 120 that is used in controlling various components of the plasma processing system. As further shown in FIG. 1, the control module 120 may be connected to the heater 122, thermocouple 124, bias match circuitry 118, RF generator 116, and TCCT Match Circuitry 114. In one embodiment, the control module 120 is configured to activate the heater 122 when the RF power from the RF generator 116 is not supplied to the TCP coils 110. In another embodiment, the control module 120 is configured to deactivate the heater 122 when the RF power is supplied to the TCP coils 110.

In accordance with another embodiment, the control module 120 is configured to activate the heater 122 so that the heating element 105 can produce heat and place the dielectric window 106 at a steady state temperature. In some embodiments, the steady state temperature can be an approximate process temperature of the dielectric window 106 when radio frequency (RF) power is supplied to the TCP coil 110. In some embodiments, the control module 120 is configured to activate or deactivate the heater 122 when the thermocouple 124 identifies the temperature of the dielectric window 106 are not within the range of the steady state temperature. The operation of the control module 120 can monitor the temperature of the dielectric window 106 to ensure that the dielectric window stays within range of the steady state temperature so that active processing of the wafers begins with the dielectric window 106 already at the desired steady state temperature.

In one embodiment, the thermocouple 124 is connected to the heating element 105, so the temperature of the dielectric window 106 is not directly sensed. However, by sensing the temperature of the heating element 105, the temperature of the dielectric window 106 can be accurately approximated. In alternative embodiments, one or more thermocouples may be added to sense temperatures of different radial locations of the heating element 105 or sensors can be directly connected to different locations of the dielectric window 106. Therefore, as used herein, the sensing of the temperature of the dielectric window 106 can either be an approximation based on sensed temperatures of the heating element 106 by one or more thermocouples, or direct sensing of temperature at one or more location of surfaces of the dielectric window 106.

In accordance with another embodiment, the control module 120 may be connected to the TCCT Match Circuitry 114 and the RF generator 116. The control module 120 can be configured to ensure that power is appropriately provided to the inner coils 112 and outer coils 111.

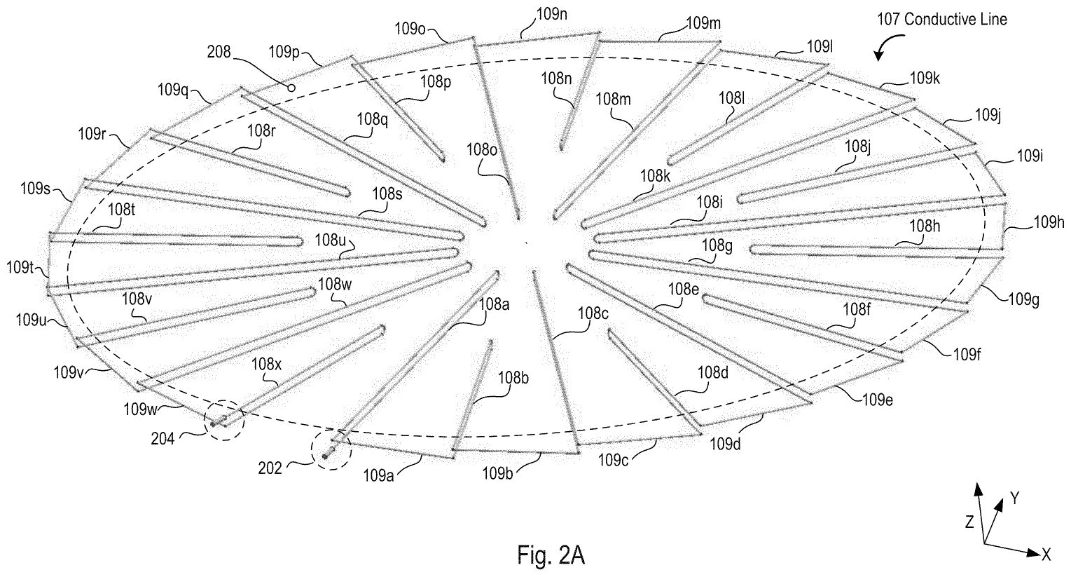

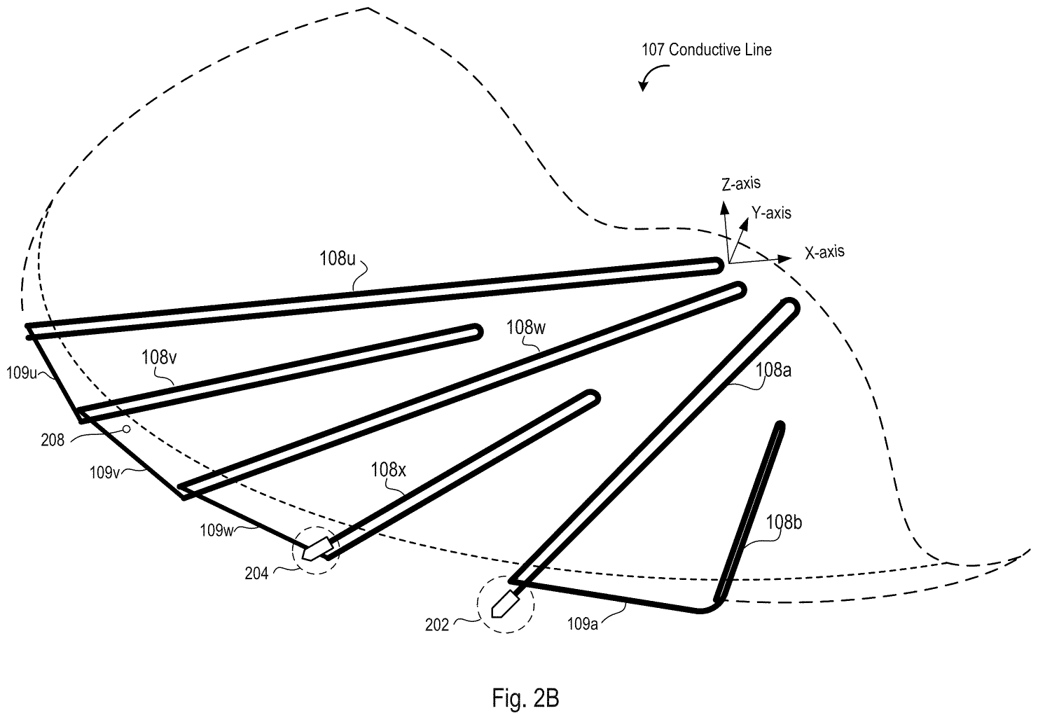

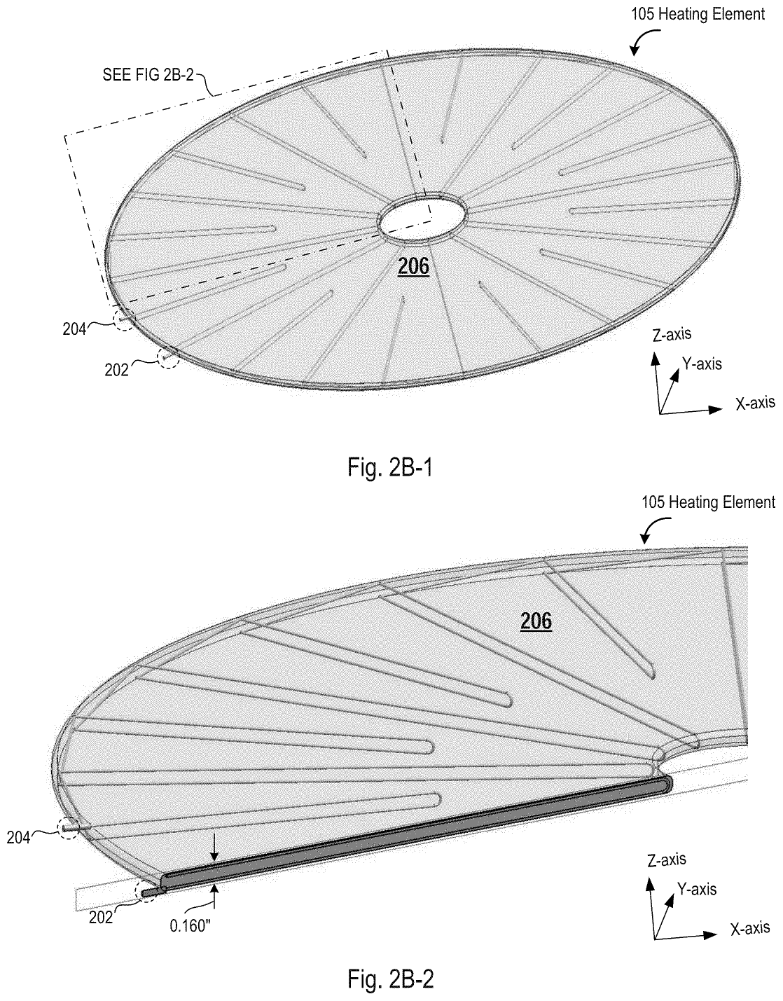

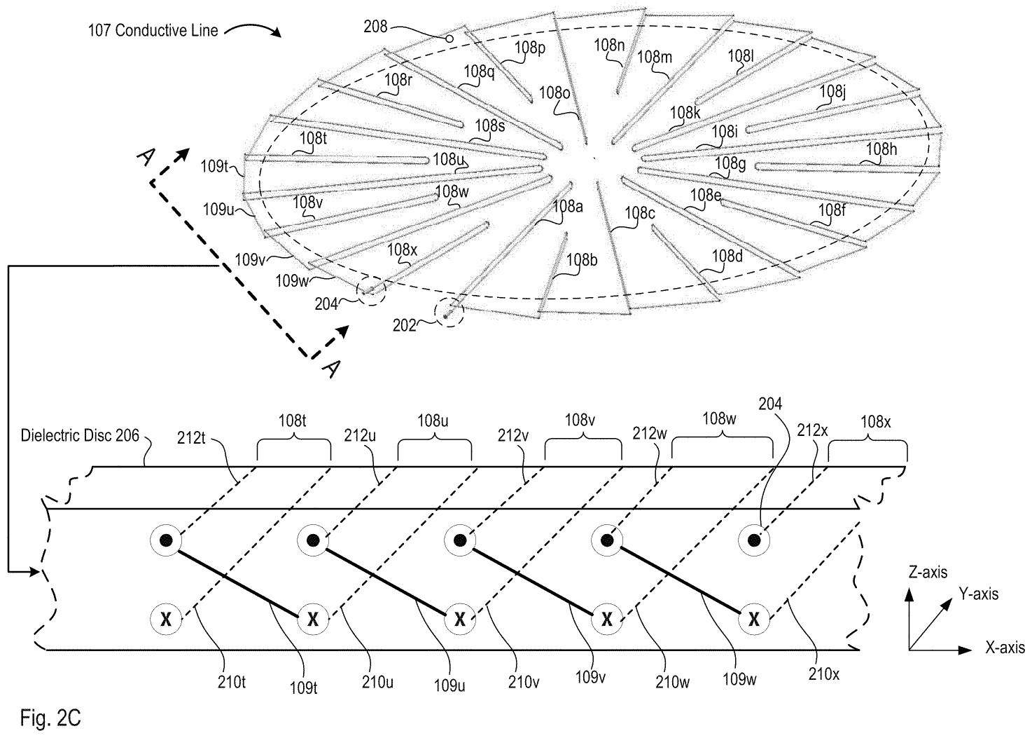

FIG. 2A illustrates an embodiment of a conductive line 107 before it is encased in a dielectric disc (not shown). As shown in FIG. 2A, the conductive line 107 is made out of a single continuous conductive line or multiple strands of conductive line that is formed into a shape of wire structure. The conductive line 107 includes a first end 202 and a second end 204 which are input and output connections that can be connected to the heater 122. When the heater 122 is activated, the conductive line 107 can produce heat from the resistance of the conductive line 107. The conductive line 107 includes a plurality of loops 108 oriented radially around the dielectric disc. Each loop 108 extends from a radial periphery 208 toward a center of the dielectric disc. In some embodiments, the length of each loop 108 may vary and the arrangement of the loops may alternate based in its length as disposed around the dielectric disc. For example, as shown in FIG. 2A, as the loops 108a-108w are disposed around the dielectric disc, the loops alternate between a short and long loop. In other embodiments, the length of each loop 108 may be the same or vary in length, and the arrangement around the dielectric disc may be configured in any configuration to achieve the desired heating requirements.

Each loop 108 of the conductive line 107 includes an inward segment that is coupled to a return segment by a switchback segment. The inward segment and the return segment are vertically aligned in the z-direction (e.g., along the thickness of the dielectric disc) and is designed to minimize RF coupling that may occur between the TCP coil 110 and the conductive line 107. As further illustrated in FIG. 2A, each loop 108 is connected to an adjacent loop by radial returns 109a-109w along the radial periphery 208 of the conductive line 107. For example, as illustrated, loops 108a and 108b are connected by radial return 109a.

In some embodiments, the cross-section shape, material and gauge of the conductive line 107 may vary and depend on the desired heating requirements, and the configuration of the plasma processing system. In some embodiments, the cross-section shape of the conductive line 107 can be a flat strip, round strip, rectangular strip, a braided wire, etc. The conductive line 107 can be configured to form any path in order to meet the desired heating requirements. For example, the conductive line 107 can be fabricated from a round strip shaped resistive material such as nickel-chromium, and the gauge can range from 15-28 American wire gauge (AWG).

FIG. 2B illustrates an enlarged partial view of a section of the conductive line 107 shown in FIG. 2A. In particular, FIG. 2B illustrates a portion of the conductive line 107. As shown, loops 108a and 108b are connected by radial return 109a, and loops 108u-108x are connected by radial returns 109u-109w, respectively. The radial returns 109 are along the perimeter of the conductive line 107. Loop 108a has an inward segment (e.g., lower level) that extends from the radial periphery 208 toward a center point, and a return segment (e.g., upper level) that extends from the center point toward the radial periphery 208. Loop 108a also includes a switchback segment that is located toward the center point which has a path in the z-direction. The switchback segment forms a shape of a semi-circle is used to couple the inward segment to the return segment. As shown, the configuration of the loop 108a results in the inward segment and the return segment being aligned over one another in the z-direction which helps reduce RF coupling. In addition, the radial return 109a connects loop 108a and 108b along the radial periphery 208 of the conductive line. Similarly, loops 108u-108x has a similar configuration as loop 108a where the inward segment and the return segment of the respective loops are aligned over one another in the z-direction.

FIG. 2B-1 illustrates an embodiment of a heating element 105. In particular, FIG. 2B-1 illustrates the conductive line 107 encased in a dielectric disc 206. The dielectric disc 206 is be made of a dielectric material (e.g. silicone rubber, or a ceramic) that has a high dielectric constant and is resistant to extreme environments and temperatures (e.g., greater than 300 Celsius). In some embodiments, encasing the conductive line in the dielectric disc 206 may help prevent electrical arching from occurring. For example, the dielectric disc 206 provides electrical insulation between the conductive line 107 and the TCP coils 110, and as well as between the conductive line 107 itself. In some embodiments, the dielectric disc 206 can be fabricated using various techniques. For example, a mold cavity fixture can be designed to encapsulate the conductive line 107. The mold cavity fixture may include an orifice that is configured to receive a melted dielectric material. Once the melted dielectric material is injected into the orifice of the mold cavity fixture, the dielectric disc is created after the melted dielectric material hardens. After the melted dielectric material hardens, the mold cavity fixture is removed which results in the conductive line 107 being formed in the dielectric disc 206.

FIG. 2B-2 illustrates an enlarged partial view of a section of the heating element 105 shown in FIG. 2B-1. In the illustrated embodiment, the heating element 105 has a thickness of approximately 0.160″ inches. In other embodiments, the thickness of the heating element 105 may be designed to be greater or less than 0.160″ to still fit between the TCP coils 110 and the dielectric window 106, and to meet the desired heating requirements.

FIG. 2C illustrates an embodiment of the heating element 105 and a section view of the heating element 105. As shown, view A-A illustrates loops 108t-108x connected by radial returns 109t-109w along the radial periphery 208 of the dielectric disc 206. In the illustrated embodiment, each loop includes an inward segment 210 (e.g. lower level) that is coupled to a return segment 212 (e.g. upper level) by a switchback segment 214 (not shown). For example, the inward segment 210t of loop 108t extends from the radial periphery 208 of the dielectric disc 206 toward a center of the dielectric disc 206. The switchback segment 214t (not shown) of the loop 108t is configured to couple the inward segment 210t to the return segment 212t of the loop 108t. The return segment 212t extends from the center of the dielectric disc 206 toward the radial periphery 208 of the dielectric disc 206 where the return segment 212t is vertically aligned with the inward segment 210t with respect to the z-axis (e.g., thickness of the dielectric disc). As shown, the conductive line 107 is defined by a continuous length where loop 108t connects to loop 108u by radial return 109t. In particular, the radial return 109t extends from the return segment 212t of loop 108t toward the inward segment 210u of loop 108u.

The inward segment 210u of loop 108u continues from the radial periphery 208 of the dielectric disc 206 toward a center of the dielectric disc 206. The switchback segment 214u (not shown) of the loop 108u is configured to couple the inward segment 210u to the return segment 212u of the loop 108u. The return segment 212u extends from the center of the dielectric disc 206 toward the radial periphery 208 of the dielectric disc 206 where the return segment 212u is vertically aligned with the inward segment 210u with respect to the z-axis. The radial return 109u extends from the return segment 212u toward the inward segment 210v of loop 108v.

The inward segment 210v of loop 108v continues from the radial periphery 208 of the dielectric disc 206 toward a center of the dielectric disc 206. The switchback segment 214v (not shown) of the loop 108v is configured to couple the inward segment 210v to the return segment 212v of the loop 108v. The return segment 212v of loop 108v extends from the center of the dielectric disc 206 toward the radial periphery 208 of the dielectric disc 206 where the return segment 212v is vertically aligned with the inward segment 210v with respect to the z-axis. The radial return 109v extends from the return segment 212v of loop 108v toward the inward segment 210w of loop 108w.

The inward segment 210w of loop 108w continues from the radial periphery 208 of the dielectric disc 206 toward a center of the dielectric disc 206. The switchback segment 214w (not shown) of the loop 108w is configured to couple the inward segment 210w to the return segment 212w. The return segment 212w of loop 108w extends from the center of the dielectric disc 206 toward the radial periphery 208 of the dielectric disc 206 where the return segment 212w is vertically aligned with the inward segment 210w with respect to the z-axis. The radial return 109w extends from the return segment 212w of loop 108w toward the inward segment 210x of loop 108x.

The inward segment 210x of loop 108x continues from the radial periphery 208 of the dielectric disc 206 toward a center of the dielectric disc 206. The switchback segment 214x (not shown) of the loop 108x is configured to couple the inward segment 210x to the return segment 212x. The return segment 212x of loop 108x extends from the center of the dielectric disc 206 toward the radial periphery 208 of the dielectric disc 206 where the return segment 212x is vertically aligned with the inward segment 210x with respect to the z-axis. In some embodiments, the second end 204 (e.g., output connection) of conductive line 107 terminates along the radial periphery 208 of return segment 212x.

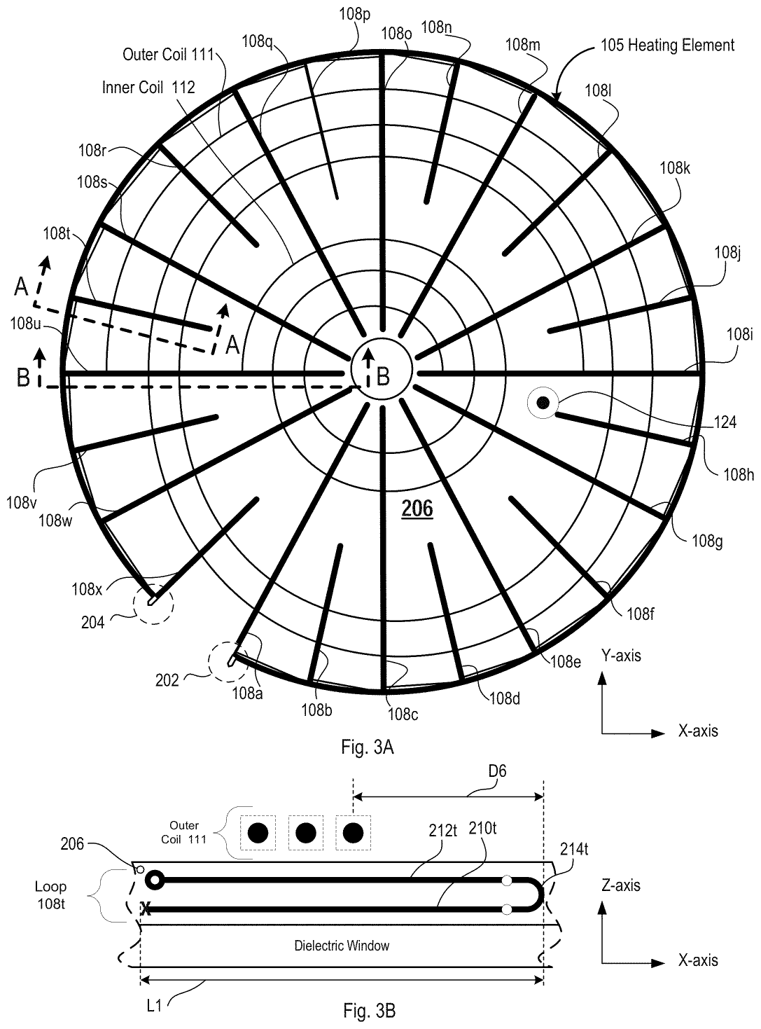

FIG. 3A illustrates an embodiment of a partial top view of a plasma processing system. The relative positions of the TCP coil 110, the heating element 105, and the thermocouple 124 are shown by way of example. In some embodiments, the TCP coil 110 includes the outer coil 111 and the inner coil 112. The outer coil 111 and inner coil 112 are disposed over the heating element 105 and the dielectric window 106. The outer coil 111 includes a plurality of circular coils that are configured to encircle the chamber 102 and to provide an electric field to the gas in the chamber 102. The inner coil 112 includes a plurality of circular coils that are configured to encircle the chamber 102 and to provide an electric field to the gas in the chamber 102. As shown, the outer coil 111 has a larger diameter than the inner coil 112. In one embodiment, the heating element 105 may include a thermocouple 124 that can be used to measure the temperature of the heating element 105 and by approximation the dielectric window 106.

As noted above, the heating element 105 includes a conductive line 107 formed in the dielectric disc 206. As shown, the conductive line 107 has a plurality of loops 108a-108x oriented radially around the dielectric disc 206. In some embodiments, the plurality of loops 108a-108x may have a first length and a second length, and the first and second lengths may be defined by their respective switchback segments. In some embodiments, the first length and the second length alternates as they are disposed around the dielectric disc. For example, loops 108a, 108c, and 108e each has a first length of 5-inches, and loops 108b, 108d, and 108f each has a second length of 3-inches. As illustrated, the length of loops 108a-108f alternates as they are disposed around the dielectric disc, e.g., 5-inch, 3-inch, 5-inch, 3-inch, etc.

FIG. 3B illustrates a partial cross-sectional view of the outer coil 111, the heating element 105, and the dielectric window 106 taken along line A-A of FIG. 3A. As illustrated, loop 108t of heating element 105 is disposed below the outer coil 111 and over the dielectric window 106. As noted above, each loop is designed to include an inward segment 210 that is coupled to a return segment 212 by a switchback segment 214. In particular, the cross-sectional view illustrates the inward segment 210t of loop 108t extending from the radial periphery 208 of the dielectric disc 206 toward a center of the dielectric disc 206. The switchback segment 214t of the loop 108t forms a shape of a semi-circle and couples the inward segment 210t to the return segment 212t. The return segment 212t extends from the center of the dielectric disc 206 toward the radial periphery 208 of the dielectric disc 206. In some embodiments, the return segment 212t is vertically aligned with the inward segment 210t with respect to the z-axis (e.g., thickness of dielectric disc). In one embodiment, the inward segment may be disposed over the return segment or the return segment may be disposed over the inward segment.

In some embodiments, to minimize RF coupling that may occur between the TCP coil 110 and the heating element 105, the switchback segment 214 of each loop 108 are not arranged in areas that are within the areas of the circular coils of the outer coil 111 or inner coil 112. For example, as shown in FIG. 3B, the switchback segment 214t does not sit directly under the outer coil and is not within the area of outer coil 111. To prevent and/or minimize RF coupling, the switchback segment 214t is designed so that there is a sufficient amount of distance separating the switchback segment from the outer and inner coils. In one example, the switchback segment 214t is disposed at a distance D6 that can range from about 0- to about 5.5 inches from the overlying coil turn. In another embodiment, RF coupling is minimized by designing the radial return 109 of each loop 108 so that they are not positioned directly under the coils or arranged in areas of the circular coils.

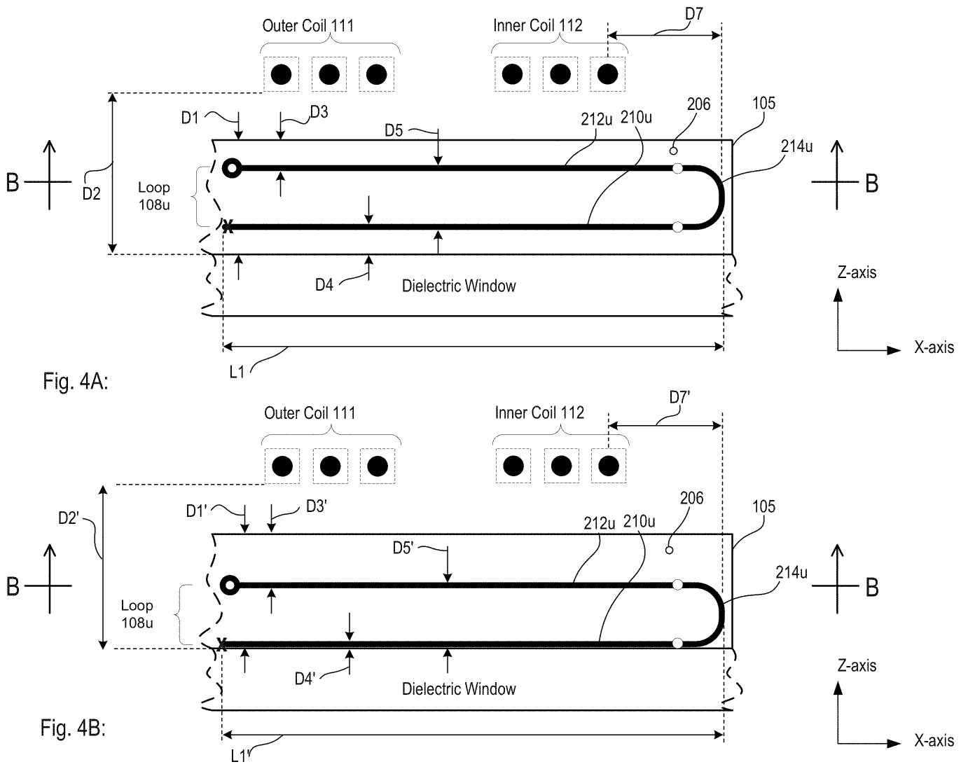

FIG. 4A and FIG. 4B illustrate various embodiments of the heating element 105 and the respective positions of the outer coil 111, inner coil 112, and dielectric window 106 taken along line B-B of FIG. 3A. FIGS. 4A-4B illustrate a partial cross-sectional view of the TCP coil 110 (e.g., outer coil 111, inner coil 112), the heating element 105, and the dielectric window 106 of a process chamber. The illustration shows the heating element 105 disposed over the dielectric window 106 and below the outer coil 111 and the inner coil 112. As noted, the heating element 105 includes a conductive line 107 encapsulated by the dielectric disc 206. The conductive line 107 includes a plurality of loops 108 oriented radially around the dielectric disc 206.

Referring to FIG. 4A, an embodiment of the heating element 105 shows the position of the conductive line 107 when it is formed in the dielectric disc 206. In particular, the conductive line 107 is vertically centered with respect to the thickness of the heating element 105. The thickness of the heating element 105 defined by thickness D1. Thickness D1 of the heating element 105 extends from a bottom surface the heating element 105 to a top surface of the heating element 105. In one embodiment, the thickness D1 of the heating element 105 may be about 0.125″ inches. Distance D2 is defined by a distance extending from the bottom surface of the heating element 105 to a bottom portion of the outer coil 111 and the inner coil 112. In some embodiments, distance D2 may be approximately 0.160″ inches. Distance D3 is defined by a distance extending from an inner surface of the return segment 212 of loop 108 to the top surface of the heating element 105. In some embodiments, distance D3 may be approximately 0.025″ inches. Distance D4 is defined by a distance extending from the bottom surface of the heating element 105 to an inner surface of the inward segment 210u of loop 108u. In some embodiments, distance D4 may be approximately 0.025″ inches. Distance D5 is defined by a distance extending from an outer surface of the inward segment 210u to an outer surface of the return segment 212u. In some embodiments, distance D5 may be approximately 0.100″ inches. The loop 108 of the conductive line may have a length defined by L1. Distance D7 is defined by a distance extending from an outer portion of the switchback segment 214u to a center point of an inner-most coil of the inner coil 112. Length L1 may extend from the radial periphery of the dielectric disc toward an outer portion of the switchback segment 214u.

In some embodiments, length L1 can be configured to be any length so that the switchback segment 214u and the radial return 109u do not sit directly under the outer coil 111 and the inner coil 112. For example, the switchback segment 214u is disposed at a distance D7 that can range from about 1 inch to about 5 inches. Referring to FIG. 4B, the figure illustrates an embodiment of the heating element 105 and the position of the conductive line 107 when it is formed in the dielectric disc 206. In particular, the conductive line 107 is vertically off-centered with respect to the thickness of the heating element 105 such that the inward segment 210u is substantially adjacent to the bottom surface the heating element 105. The thickness of the heating element 105 may have a thickness defined by D1′. Thickness D1′ of the heating element 105 may extend from a bottom surface the heating element 105 to a top surface of the heating element 105. In one embodiment, the thickness D1′ of the heating element 105 is approximately 0.125″ inches. Distance D2′ is defined by a distance extending from the bottom surface of the heating element 105 to the bottom portion of the outer coil 111 and the inner coil 112. In some embodiments, distance D2′ may be approximately 0.160″ inches. Distance D3′ is defined by a distance extending from the inner surface of the return segment 212u to the top surface of the heating element 105. In some embodiments, distance D3′ may be approximately 0.025″ inches. Distance D4′ is defined by a distance extending from the bottom surface of the heating element 105 to the inner surface of the inward segment 210u of loop 108u. In this embodiment, since the inward segment 210u sits substantially against an inner bottom surface the heating element 105, distance D4′ is the diameter of the conductive line 107. Distance D5′ is defined by a distance extending from the outer surface of the inward segment 210u to the outer surface of the return segment 212u. In some embodiments, distance D5′ may be approximately 0.100″ inches. Distance D7′ is defined by a distance extending from an outer portion of the switchback segment 214u to a center point of an inner-most coil of the inner coil 112. The switchback segment 214u is disposed at a distance D7′ that can range from about 1 inch to about 5 inches from the overlying coil turn. Length L1′ may extend from the radial periphery of the dielectric disc toward an outer portion of the switchback segment 214u. As noted above, length L1′ can be any length so that the switchback segment 214u and the radial return 109u does not sit directly under the outer coil 111 and the inner coil 112.

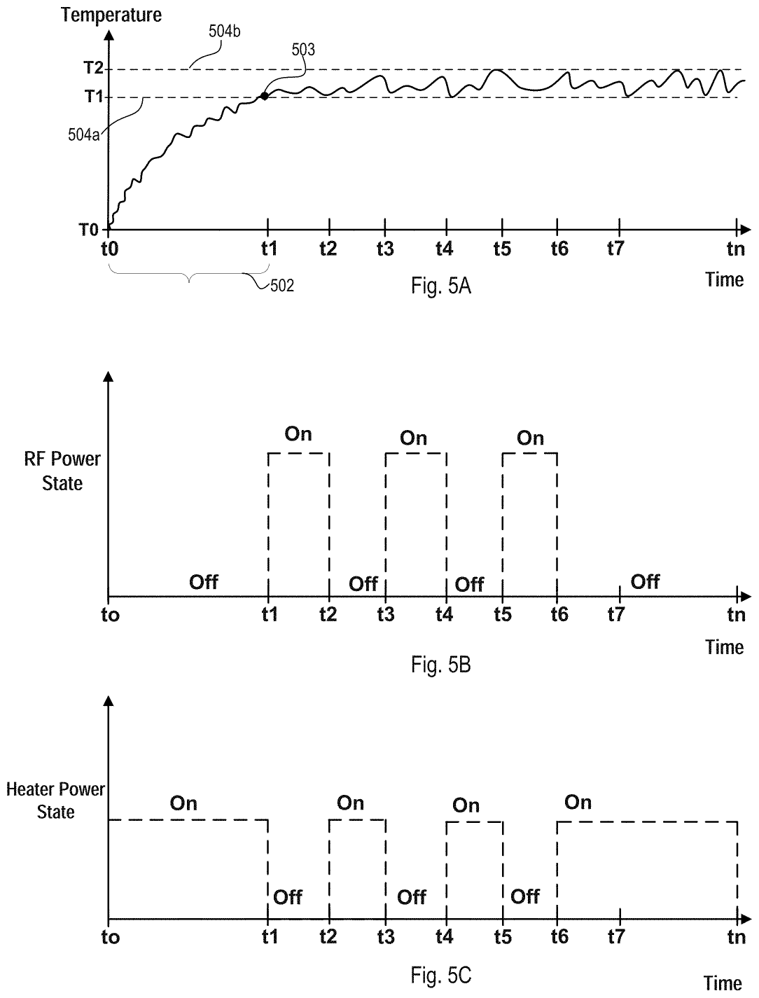

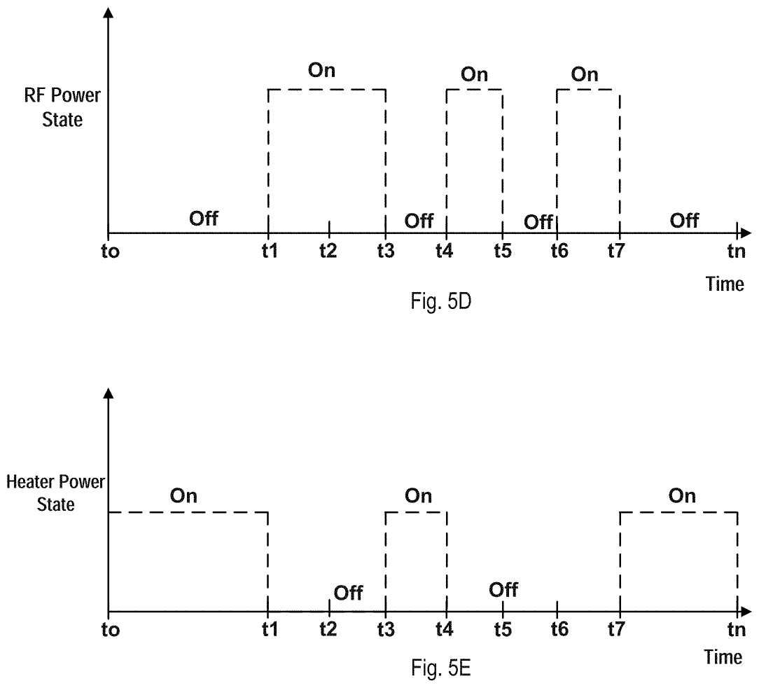

FIGS. 5A-5E illustrate an embodiment of a temperature plot of the dielectric window 106 and the respective power activity of the RF power and the heater power over a period of time. In some embodiments, at the start of a processing operation, the heating element 105 may be used during a warm-up period 502 to deliver heat to the dielectric window so that the temperature of the dielectric window can reach a desired steady state temperature so that active processing 503 begins with the dielectric window 106 at the desired steady state temperature. In one embodiment, active processing occurs after the TCP coils are powered and process gases have been delivered to the TCP chamber 102. This steady state temperature may be an approximate process temperature of the dielectric window when RF power is supplied to the TCP coils. It is desired that active processing 503 begins with the dielectric window 106 at the steady state temperature because it helps remove variations in plasma conditions that could reduce etch performance.

In one embodiment, referring simultaneously to FIGS. 5A, 5B, and 5C, the figures illustrate a temperature plot of dielectric window 106 and the power state of the RF power and the heater power used to supply power to the TCP coils 110 and the heating element 105, respectively. For example, at start of a processing operation (e.g., time t0), the heater power for the heating element 105 is activated at time t0 and the temperature of the dielectric window 106 begins to increase. The temperature of the dielectric window 106 steadily increases during a warm-up period 502 (e.g., time t0-t1) until it reaches a steady state temperature. The steady state temperature may range between a lower limit and an upper limit, e.g., 504a-504b. Once the dielectric window 106 is at a steady state temperature 504a-504b, active processing 503 operations can begin. As illustrated in FIGS. 5B and 5C, during the warm-up period 502 (e.g., time t0-t1), while the heater power for the heating element 105 is activated, the RF power for the coils are deactivated. Accordingly, in one embodiment, during the warmup period 502, only the heating element 105 is utilized to deliver heat to the dielectric window 106 so that the dielectric window can reach the appropriate processing temperature 503.

Once the active processing 503 of the substrate is initiated (e.g., time t1), the RF generator 116 for suppling RF power to the TCP coils 110 is activated and the heater power for supplying power to the heating element 105 is deactivated. As illustrated, active processing 503 may include various processing operations from time t1-tn which can result in the RF power and the heater power being in an active or inactive state. For example, as shown in FIG. 5B, the RF power may be active at time t1-t2, t3-t4, t5-t6, and inactive at time t0-t1, t2-t3, t4-t5, and t6-tn. As shown in FIG. 5C, the heater power may be inactive at time t1-t2, t3-t4, t5-t6, and active at t0-t1, t2-t3, t4-t5, and t6-tn. Since the active processing 503 operations may include various steps and processes (e.g., chamber pressure, specific gases, gas ratios, pulsing of RF power and gases, wafer transferring, etc.), the RF power may alternate between active and inactive periods to meet the necessary processing steps. In some embodiments, when the RF power is active, the heater power may be inactive. In one embodiment, when the RF power is inactive, the heater power may be active so that the heating element 105 produces heat so that the temperature of the dielectric window 106 stays within the steady state temperature, e.g., 504a-504b. In other words, for a given time, either the RF power or the heater power is active so that the dielectric window 106 maintains the steady state temperature so that active processing begins with the dielectric window 106 already at the desired steady state temperature.

In accordance with another embodiment, referring simultaneously to FIGS. 5A, 5D and 5E, the figures illustrate the temperature plot of dielectric window 106 and the power state of the RF power and the heater power. As shown in FIG. 5E, during warm-up period 502 (e.g., time t0-t1), the heater power is active and the heating element 105 raises the temperature of the dielectric window 106 to a steady state temperature. Referring to FIGS. 5D and 5E, when active processing 503 operations begin at time t1, the RF generator 116 for suppling RF power to the TCP coils 110 is activated and the heater power for supplying power to the heating element 105 is deactivated. During the processing operations, as shown in FIG. 5D, the RF power may be active at time t1-t3, t4-t5, t6-t7, and inactive at time t0-t1, t3-t4, t5-t6, and t7-tn. As shown in FIG. 5E, the heater power may be inactive at time t1-t3, t4-t7, and active at t0-t1, t3-t4, and t7-tn. In some embodiments, both the RF power and the heater power may be in an inactive state, e.g., time t5-t6. For example, in this embodiment, at time t5-t6, the temperature of the dielectric window 106 may be on the verge of exceeding the upper limit of the steady state temperature (e.g., Figure SA, 504b). Accordingly, the system may deactivate both the RF power and the heater power to ensure that the dielectric window 106 stays within the desired steady state temperature 504a-504b.

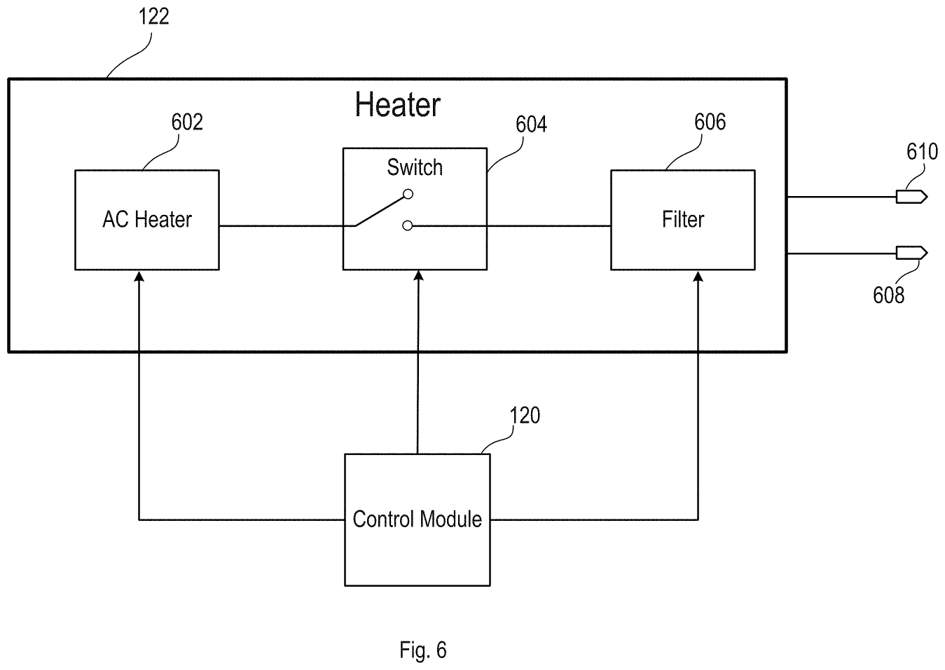

FIG. 6 illustrates an embodiment of a block diagram of a heater 122 used to connect to the heating element 105 to produce heat when the heater 122 is activated. In one embodiment, the heater 122 includes an alternating current (AC) heater 602, a switch 604, a filter 606, a first terminal 608, a second terminal 610, and a control module 120. The AC heater 602 is a power source and is configured to supply power to the heating element 105 when the first terminal 608 and the second terminal 610 are connected to the first end and second end of the heating element 105. In some embodiments, the AC heater 602 can be connected to the switch 604. The switch 604 is configured to be in an open position or a closed position. When the switch 604 is in an open position, the power flow supplied by the AC heater 602 is interrupted and power cannot be delivered to the heating element 105. However, when the switch 604 is in a closed position, the power flow from the AC heater 602 is uninterrupted and power can be delivered to the heating element 105. In some embodiments, the switch 604 may be connected to the filter 606. The filter 606 may be configured to prevent the AC heater 602 from burning out when the RF power state is active. For example, when the RF power state is activated to deliver RF power to the coils, the filter 606 is configured to attenuate electromagnetic interference (EMI) or radio frequency interference that may potentially occur.

In some embodiments, the control module 120 may be used to control various components of the heater 122 to is configured to regulate the delivery of power to the heating element 105. As illustrated in FIG. 6, the control module 120 may be connected the AC heater 602, the switch 604, and the filter 606. This configuration allows the control module to synchronize and control the operation of the AC heater, the switch, and the filter in order to optimization the operation of the heater 122. For example, the control module 120 is configured to deactivate the heater 122 when the RF power is being supplied to the TCP coils. In another embodiment, the control module 120 can monitor the temperature of the dielectric window 106 (e.g., using thermocouple 124) to determine whether the dielectric window 106 at steady state temperature. If the temperature of the dielectric window 106 is at risk of falling outside the range of the steady state temperature, the control module 120 can activate or deactivate the heater 122 to ensure that the dielectric window 106 stays within the range of the steady state temperature.

In some embodiments, a user interface may be associated with the control module 120. The user interface may include a display screen and user input devices such as pointing devices, keyboards, touch screens, microphones, etc.

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller module 120 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

Although the foregoing embodiments have been described in some detail for purposes of clarity of understanding, it will be apparent that certain changes and modifications can be practiced within the scope of the appended claims. Accordingly, the present embodiments are to be considered as illustrative and not restrictive, and the embodiments are not to be limited to the details given herein, but may be modified within their scope and equivalents of the claims.

What is claimed is:

1. A heating element, comprising:
a dielectric disc; and
a conductive line formed in the dielectric disc, the conductive line having a plurality of loops oriented radially around the dielectric disc, each loop extending from a radial periphery of the dielectric disc toward a center of the dielectric disc,
wherein each loop of the conductive line has an inward segment coupled to a return segment by a switchback segment, and the inward segment is vertically aligned with the return segment.

2. The heating element of claim 1, wherein each of the plurality of loops is defined by a continuous length of said conductive line, and a first end of the conductive line defines an input connection and a second end of the conductive line defines an output.

3. The heating element of claim 2, wherein a heater is connected to the first end and the second end, and the conductive line is a resistive element that produces heat when the heater is activated.

4. The heating element of claim 1, wherein each of said loops is connected by radial returns along the radial periphery.

5. The heating element of claim 1, wherein the plurality of loops have a first length and a second length, wherein the first and second lengths are defined by respective switchback segments, and wherein the first length and the second length alternate as disposed around the dielectric disc.

6. The heating element of claim 1, wherein the dielectric disc has a thickness, and a vertical alignment of the inward segment and the return segment are each oriented along the thickness.

7. The heating element of claim 1, wherein the inward segment is disposed over the return segment or the return segment is disposed over the inward segment.

8. The heating element of claim 1, wherein the dielectric disc having the conductive line is configured for placement over a dielectric window of a plasma chamber.

9. The heating element of claim 1, further comprising,
a heater, the heater including an alternating current (AC) heater, a switch, and a filter, wherein a controller is configured to control the AC heater, the switch and the filter;
wherein the dielectric disc having the conductive line is configured for placement over a dielectric window of a plasma chamber, the plasma chamber having coils disposed over the dielectric window for receiving radio frequency (RF) power, wherein the switchback segment for each loop are not arranged in areas that is proximate to circular coils of the inner coil and the outer coil.

10. The heating element of claim 9, wherein the controller is configured to activate the heater when RF power is not supplied to the plasma chamber and deactivate the heater when the RF power is supplied to the plasma chamber.

11. The heating element of claim 9, wherein the controller is configured to activate the heater to place a temperature of the dielectric window to a steady state temperature, the steady state temperature being an approximate process temperature of the dielectric window when the RF power is supplied to the coils of the plasma chamber.

12. A system, comprising:
a process chamber having a dielectric window, and said dielectric window being oriented over a substrate support;
a coil defined by an inner coil and an outer coil, the coil oriented over the dielectric window, wherein the inner coil and the outer coil includes a plurality of circular coils;
a heating element disposed over the dielectric window and below the coil, the heating element including,
a dielectric disc; and
a conductive line formed in the dielectric disc, the conductive line having a plurality of loops oriented radially around the dielectric disc, each loop extending from a radial periphery of the dielectric disc toward a center of the dielectric disc,
wherein each loop of the conductive line has an inward segment coupled to a return segment by a switchback segment, and the inward segment is vertically aligned with the return segment.

13. The system of claim 12, wherein each of the plurality of loops is defined by a continuous length of said conductive line, and a first end of the conductive line defines an input connection and a second end of the conductive line defines an output.

14. The system of claim 12, further comprising,
a controller, the controller connected to a heater and the heater is coupled to a first end and a second end of the conductive line;
wherein the controller is configured to activate the heater to bring the dielectric window to a steady state temperature, the steady state temperature being an approximate process temperature of the dielectric window when radio frequency (RF) power is supplied to the coil.

15. The system of claim 12, further comprising,
a controller, the controller connected to a heater and the heater is coupled to a first end and a second end of the conductive line;
wherein the controller is configured to activate the heater when radio frequency (RF) power not supplied to the coil and a thermocouple identifies a temperature of the dielectric window to be outside a steady state temperature.

16. The system of claim 12, wherein each of said loops is connected by radial returns along the radial periphery, wherein said radial returns are not arranged in areas that are proximate to the circular coils of the inner coil and the outer coil.

17. The system of claim 12, wherein the plurality of loops have a first length and a second length, wherein the first and second lengths are defined by respective switchback segments, and wherein the first length and the second length alternate as disposed around the dielectric disc.

18. The system of claim 12, wherein the switchback segment of each loop is not arranged in areas that are proximate to the circular loops of the inner coil and the outer coil.
